(19) United States
(12) Patent Application Publication
(10) Pub. No.: US 2025/0142852 A1
(43) Pub. Date: May 1, 2025

(54) SEMICONDUCTOR APPARATUS

(71) Applicant: Mitsubishi Electric Corporation, Tokyo (JP)

(72) Inventors: Reona FURUKAWA, Tokyo (JP); Shinya SONEDA, Tokyo (JP)

(73) Assignee: Mitsubishi Electric Corporation, Tokyo (JP)

(21) Appl. No.: 18/911,136

(22) Filed: Oct. 9, 2024

(30) Foreign Application Priority Data
Oct. 26, 2023 (JP) 2023-183823

(51) Int. Cl. H01L 29/739; H01L 23/495; H01L 29/06; H01L 29/861

(52) U.S. Cl. CPC H10D 12/481; H01L 23/49562; H10D 8/00; H10D 62/127

(57) ABSTRACT

An interconnection member has a bonded surface in contact with a bonding member. In plan view seen in a direction perpendicular to a front surface electrode, the bonded surface covers at least a portion of each of a plurality of diode regions. The plurality of diode regions include a first diode region, a second diode region, and a third diode region. In plan view, the second diode region is located in a first direction with respect to the first diode region and is spaced from the first diode region. In plan view, the third diode region is located in a second direction, which is perpendicular to the first direction, with respect to the first diode region, and is spaced from each of the first diode region and the second diode region.

### CROSS REFERENCE TO RELATED APPLICATIONS

This nonprovisional application is based on Japanese Patent Application No. 2023-183823 filed on Oct. 26, 2023 with the Japan Patent Office, the entire contents of which are hereby incorporated by reference.

### BACKGROUND OF THE INVENTION

### Field of the Invention

The present disclosure relates to a semiconductor apparatus.

### Description of the Background Art

An insulated gate bipolar transistor (IGBT), a reverse conducting insulated gate bipolar transistor (RC-IGBT), and other similar semiconductor devices generate heat when they conduct, start conduction, and end conduction. The heat generation may shorten the life of a semiconductor apparatus on which the semiconductor device is mounted. This impairs the semiconductor apparatus in reliability. Accordingly, there is a need for a technique for dissipating heat generated as a semiconductor device generates heat.

As an example of a semiconductor apparatus, Japanese Patent Application Laying-Open No. 2022-158037 discloses a semiconductor device having an RC-IGBT chip disposed on a copper circuit pattern. The semiconductor device has a wire bonded to a surface electrode (an emitter electrode) of the RC-IGBT. The wire is used as an external wiring.

### SUMMARY OF THE INVENTION

When the RC-IGBT short-circuits, the RC-IGBT generates heat in an IGBT region. In particular, the IGBT region generates heat at a portion close to the surface electrode. The semiconductor device described in Japanese Patent Application Laying-Open No. 2022-158037 has the RC-IGBT with a surface externally, electrically connected using a wire. Therefore, heat generated at a portion of the RC-IGBT chip close to the surface electrode is insufficiently dissipated. The present disclosure has been made in view of the above, and an object thereof is to provide a semiconductor apparatus capable of enhanced heat dissipation at a portion close to a front surface electrode.

A semiconductor apparatus according to the present disclosure comprises an insulated gate bipolar transistor region, a plurality of diode regions, a front surface electrode, a bonding member, and an interconnection member. The plurality of diode regions are in contact with the insulated gate bipolar transistor region. The front surface electrode is in contact with the insulated gate bipolar transistor region and the plurality of diode regions. The bonding member is provided on the front surface electrode. The interconnection member is bonded to the front surface electrode by the bonding member. The insulated gate bipolar transistor region and the plurality of diode regions constitute a reverse conducting insulated gate bipolar transistor. The interconnection member has a bonded surface in contact with the bonding member. In a plan view seen in a direction perpendicular to the front surface electrode, the bonded surface covers at least a portion of each of the plurality of diode regions. The plurality of diode regions include a first diode region, a second diode region, and a third diode region. In the plan view, the second diode region is located in a first direction with respect to the first diode region and is spaced from the first diode region. In the plan view, the third diode region is located in a second direction with respect to the first diode region, the second direction being perpendicular to the first direction, and is spaced from each of the first and second diode regions.

The foregoing and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a schematic plan view showing a configuration of a semiconductor apparatus according to a first embodiment.

FIG. 2 is a schematic cross section taken along a line II-II of FIG. 1.

FIG. 3 is a schematic plan view showing a configuration of a semiconductor device.

FIG. 4 is a schematic cross section showing a configuration of the semiconductor device.

FIG. 5 is a schematic plan view showing a configuration of a semiconductor device according to a first modification of the first embodiment.

FIG. 6 is a schematic plan view showing a configuration of a semiconductor device according to a second modification of the first embodiment.

FIG. 7 is a schematic plan view showing a configuration of a semiconductor apparatus according to a third modification of the first embodiment.

FIG. 8 is a schematic plan view showing a configuration of a semiconductor apparatus according to a second embodiment.

FIG. 9 is a schematic cross section taken along a line IX-IX of FIG. 8.

FIG. 10 is a schematic plan view showing a configuration of a semiconductor device according to a third embodiment.

FIG. 11 is a schematic plan view showing a configuration of a semiconductor apparatus according to the third embodiment.

FIG. 12 is a schematic cross section taken along a line XII-XII of FIG. 11.

FIG. 13 is a schematic plan view showing a configuration of a semiconductor apparatus according to a fourth embodiment.

FIG. 14 is a schematic plan view showing a configuration of a semiconductor apparatus according to a fifth embodiment.

FIG. 15 is a schematic cross section showing a configuration of a semiconductor apparatus according to a sixth embodiment.

FIG. 16 is a schematic cross section showing a configuration of a semiconductor apparatus according to a modification of the sixth embodiment.

FIG. 17 is a schematic cross section showing a configuration of a semiconductor apparatus according to a seventh embodiment.

FIG. 18 is a schematic plan view showing a configuration of a semiconductor apparatus according to an eighth embodiment.

FIG. 19 is a schematic cross section taken along a line XIX-XIX of FIG. 18.

FIG. 20 is a schematic cross section showing a configuration of a semiconductor apparatus according to a ninth embodiment.

### DESCRIPTION OF THE PREFERRED EMBODIMENTS

Hereinafter, embodiments of the present disclosure will be described with reference to the drawings. In the following figures, identical or equivalent components are identically denoted and will not be described repeatedly.

### First Embodiment

### <Configuration of Semiconductor Apparatus>

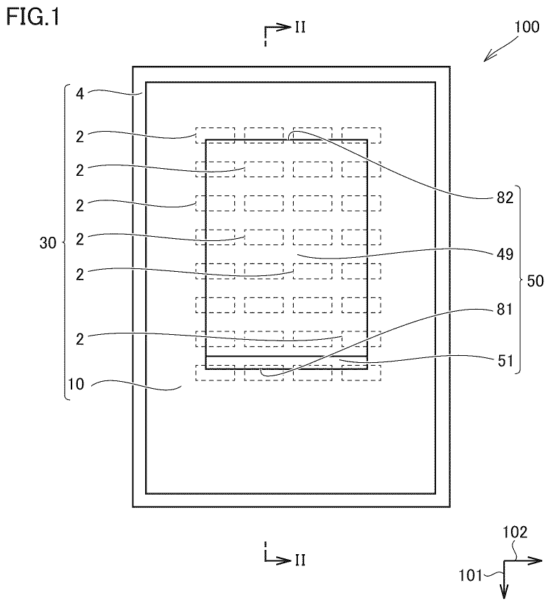

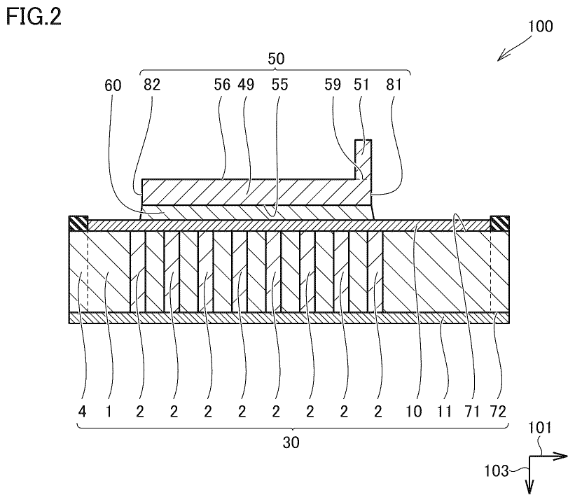

Initially, a configuration of a semiconductor apparatus 100 according to a first embodiment will be described with reference to FIGS. 1 and 2. For the sake of convenience for illustration, FIG. 1 indicates a plurality of diode regions 2, which will be described hereinafter, by a broken line.

As shown in FIGS. 1 and 2, semiconductor apparatus 100 according to the first embodiment mainly comprises a semiconductor device 30, a bonding member 60, and an interconnection member 50. Bonding member 60 bonds semiconductor device 30 and interconnection member 50 together. Interconnection member 50 electrically interconnects semiconductor device 30 and an external device (not shown).

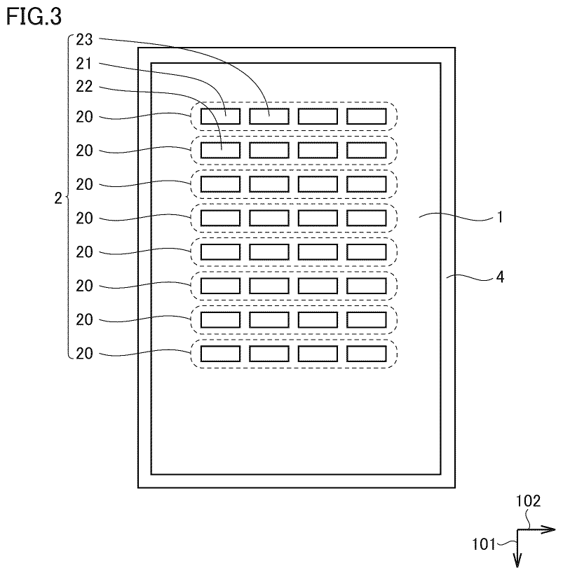

As shown in FIGS. 2 and 3, semiconductor device 30 includes a front surface electrode 10, a back surface electrode 11, an insulated gate bipolar transistor region 1, a plurality of diode regions 2, and a terminal region 4. Hereinafter, insulated gate bipolar transistor region 1 will also be referred to as an IGBT region 1.

As shown in FIG. 2, semiconductor device 30 has a first surface 71 and a second surface 72. Second surface 72 is opposite to first surface 71. A direction from first surface 71 toward second surface 72 is a third direction 103. Third direction 103 is a direction perpendicular to front surface electrode 10. Front surface electrode 10 is provided on first surface 71. Front surface electrode 10 is an emitter electrode. Back surface electrode 11 is provided on second surface 72. Back surface electrode 11 is a collector electrode.

IGBT region 1 and the plurality of diode regions 2 define first surface 71 and second surface 72. IGBT region 1 is in contact with each of front surface electrode 10 and back surface electrode 11. IGBT region 1 is electrically connected to each of front surface electrode 10 and back surface electrode 11.

As shown in FIG. 2, each of the plurality of diode regions 2 is in contact with IGBT region 1. Each of the plurality of diode regions 2 is in contact with each of front surface electrode 10 and back surface electrode 11. Each of the plurality of diode regions 2 is electrically connected to each of front surface electrode 10 and back surface electrode 11.

The plurality of diode regions 2 are spaced from one another. When viewed in a direction perpendicular to front surface electrode 10 (hereinafter also referred to as plan view), each of the plurality of diode regions 2 has a rectangular shape, for example.

Terminal region 4 is in contact with IGBT region 1. Terminal region 4 surrounds IGBT region 1 and the plurality of diode regions 2. Terminal region 4 defines a portion of second surface 72. The configuration of terminal region 4 will specifically be described hereinafter.

As shown in FIG. 2, bonding member 60 is provided on front surface electrode 10. Bonding member 60 is, for example, solder. In plan view, bonding member 60 is surrounded by terminal region 4. Bonding member 60 transfers heat from front surface electrode 10 to interconnection member 50.

Interconnection member 50 is metallically bonded to front surface electrode 10 by bonding member 60. Specifically, interconnection member 50 is electrically connected to front surface electrode 10 by bonding member 60. Interconnection member 50 is made of metal.

As shown in FIGS. 1 and 2, interconnection member 50 includes a flat plate portion 49 and a conductive plate portion 51. Interconnection member 50 is a DLB (Direct Lead Bonding) electrode. In plan view, flat plate portion 49 has a rectangular shape. Flat plate portion 49 is in contact with bonding member 60. In third direction 103, bonding member 60 is provided between flat plate portion 49 and front surface electrode 10. Flat plate portion 49 may be spaced from front surface electrode 10. In plan view, flat plate portion 49 is surrounded by terminal region 4.

As shown in FIGS. 1 and 2, flat plate portion 49 has a first end 81 and a second end 82. First end 81 extends, for example, in a direction in which a longer side of the plurality of diode regions 2 extends. Flat plate portion 49 has second end 82 provided on a side opposite to first end 81. Second end 82 may extend in a direction substantially parallel to that in which first end 81 extends, for example.

As shown in FIG. 2, flat plate portion 49 has a bonded surface 55 and a front surface 56. Bonded surface 55 is a surface of flat plate portion 49 that is in contact with bonding member 60. In other words, flat plate portion 49 is in contact with bonding member 60 on bonded surface 55. Bonded surface 55 is, for example, planar. Front surface 56 is opposite to bonded surface 55. From another viewpoint, front surface 56 is provided in a direction opposite to third direction 103 with respect to bonded surface 55.

As shown in FIG. 1, in plan view, flat plate portion 49 covers at least a portion of each of the plurality of diode regions 2. From another viewpoint, in plan view, bonded surface 55 (see FIG. 2) covers at least a portion of each of the plurality of diode regions 2.

As shown in FIGS. 1 and 2, conductive plate portion 51 is contiguous to flat plate portion 49. Specifically, for example, conductive plate portion 51 is contiguous to flat plate portion 49 at first end 81. Conductive plate portion 51 is provided, for example, in a direction opposite to third direction 103 with respect to flat plate portion 49. Conductive plate portion 51 is spaced from bonding member 60. An interface between conductive plate portion 51 and flat plate portion 49 is a connecting portion 59. In other words, conductive plate portion 51 and flat plate portion 49 are contiguous to each other at connecting portion 59. Conductive plate portion 51 constitutes a path for a current passing between front surface electrode 10 and an external device (not shown).

Conductive plate portion 51 extends in a direction substantially parallel to that in which the longer side of the plurality of diode regions 2 extends. From another viewpoint, connecting portion 59 extends in the direction in which the longer side of each of the plurality of diode regions 2 extends.

### <Configuration of Semiconductor Apparatus>

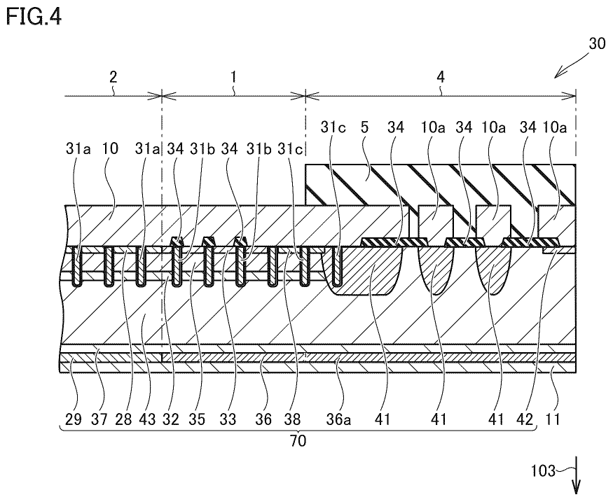

A configuration of semiconductor device 30 will now be described with reference to FIGS. 3 and 4. For the sake of convenience for illustration, front surface electrode 10 is not shown in FIG. 3. The cross section shown in FIG. 4 is a cross section perpendicular to front surface electrode 10.

As shown in FIG. 3, semiconductor device 30 is an island-type RC-IGBT. Specifically, the plurality of diode regions 2 are provided in the form of islands. From another viewpoint, two or more diode regions 2 are aligned in each of first direction 101 and second direction 102 in a region overlapping a single front surface electrode 10 in plan view.

The plurality of diode regions 2 include a first diode region 21, a second diode region 22, and a third diode region 23. First diode region 21 is, for example, diode region 2 located at a corner of the plurality of diode regions 2. Second diode region 22 is spaced from first diode region 21. In plan view, a direction from first diode region 21 toward second diode region 22 is a first direction 101. From another viewpoint, in plan view, second diode region 22 is located in first direction 101 with respect to first diode region 21.

Third diode region 23 is spaced from each of first diode region 21 and second diode region 22. In plan view, a direction from first diode region 21 toward third diode region 23 is a second direction 102. From another viewpoint, third diode region 23 is located in second direction 102 with respect to first diode region 21. Second direction 102 is a direction perpendicular to first direction 101. The plurality of diode regions 2 may each have a longer side parallel to second direction 102, for example.

As shown in FIG. 3, the plurality of diode regions 2 have a plurality of rows 20. Each of the plurality of rows 20 is composed of a plurality of diode regions 2 aligned in second direction 102. While the number of diode regions 2 included in one row 20 is not particularly limited, the row has four diode regions for example. In row 20, for example, four diode regions 2 may be aligned substantially equidistantly in second direction 102. The plurality of rows 20 are aligned in first direction 101. The plurality of rows 20 may be aligned substantially equidistantly in first direction 101, for example. While the number of rows 20 is not particularly limited, eight rows are provided, for example.

Each of the plurality of diode regions 2 is surrounded by IGBT region 1. From another viewpoint, IGBT region 1 has a portion sandwiched between two diode regions 2 in first direction 101. IGBT region 1 has a portion sandwiched between two diode regions 2 in second direction 102.

In plan view, semiconductor device 30 has a rectangular shape, for example. In plan view, semiconductor device 30 has a longer side extending in first direction 101. In plan view, semiconductor device 30 has a shorter side extending in second direction 102.

As shown in FIG. 4, semiconductor device 30 has a semiconductor substrate 70. A configuration of diode region 2 will now be described. Semiconductor substrate 70 has, for example, an n−-type drift layer 43, an n+-type carrier store layer 32, a p-type base layer 35, a p-type anode layer 28, an n-type buffer layer 37, and an n+-type cathode layer 29.

N+-type carrier store layer 32 is provided on n−-type drift layer 43. N+-type carrier store layer 32 has a higher n-type impurity concentration than n−-type drift layer 43 does. P-type base layer 35 is provided on n+-type carrier store layer 32.

P-type anode layer 28 is provided on p-type base layer 35. P-type anode layer 28 is provided in diode region 2. P-type anode layer 28 has a higher p-type impurity concentration than the p-type base layer 35 does. P-type anode layer 28 defines a portion of first surface 71 (see FIG. 2).

N-type buffer layer 37 is provided in third direction 103 with respect to n−-type drift layer 43. N-type buffer layer 37 is in contact with n−-type drift layer 43. N-type buffer layer 37 has a higher n-type impurity concentration than n−-type drift layer 43 does.

N+-type cathode layer 29 is provided in third direction 103 with respect to n-type buffer layer 37. N+-type cathode layer 29 is in contact with n-type buffer layer 37. N+-type cathode layer 29 is provided in diode region 2. N+-type cathode layer 29 is electrically connected to back surface electrode 11. N+-type cathode layer 29 defines a portion of second surface 72 (see FIG. 2).

A first trench gate 31a is provided in semiconductor substrate 70 at diode region 2. First trench gate 31a extends from first surface 71 in third direction 103. First trench gate 31a reaches n−-type drift layer 43. First trench gate 31a is electrically connected to front surface electrode 10.

A configuration of IGBT region 1 will now be described. Semiconductor substrate 70 includes an n+-type source layer 33, a p+-type contact layer 38, and a p-type collector layer 36. N+-type source layer 33 is provided on p-type base layer 35. N+-type source layer 33 is provided in IGBT region 1. N+-type source layer 33 defines a portion of first surface 71 (see FIG. 2).

P+-type contact layer 38 is provided on p-type base layer 35. P+-type contact layer 38 is provided in IGBT region 1 and terminal region 4. P+-type contact layer 38 is spaced from n+-type source layer 33. P+-type contact layer 38 has a higher p-type impurity concentration than p-type base layer 35 does. P+-type contact layer 38 may have a p-type impurity concentration equal to that of p-type anode layer 28.

P-type collector layer 36 is provided in third direction 103 with respect to n-type buffer layer 37. P-type collector layer 36 is in contact with n-type buffer layer 37. P-type collector layer 36 is provided in IGBT region 1. P-type collector layer 36 defines a portion of second surface 72 (see FIG. 2). P-type collector layer 36 is electrically connected to back surface electrode 11. P-type collector layer 36 is in contact with n+-type cathode layer 29. An interface between p-type collector layer 36 and n+-type cathode layer 29 serves as a boundary between diode region 2 and IGBT region 1.

A second trench gate 31b and a third trench gate 31c are provided in semiconductor substrate 70 at IGBT region 1. Second trench gate 31b extends from first surface 71 in third direction 103. Second trench gate 31b reaches n−-type drift layer 43. Second trench gate 31b is in contact with n+-type source layer 33. An interlayer insulating film 34 is provided on second trench gate 31b. Second trench gate 31b and front surface electrode 10 are electrically insulated from each other by interlayer insulating film 34.

Third trench gate 31c extends from first surface 71 in third direction 103. Third trench gate 31c reaches n−-type drift layer 43. Third trench gate 31c is in contact with p+-type contact layer 38. Third trench gate 31c is electrically connected to front surface electrode 10.

A configuration of terminal region 4 will now be described. Semiconductor substrate 70 has a p-type terminal well layer 41, an n+-type channel stopper layer 42, and a p-type terminal collector layer 36a.

P-type terminal well layer 41 is provided in terminal region 4. P-type terminal well layer 41 is in contact with n−-type drift layer 43. P-type terminal well layer 41 defines a portion of first surface 71 (see FIG. 2). Semiconductor substrate 70 has, for example, three p-type terminal well layers 41. The three p-type terminal well layers 41 are spaced from one another. In plan view, each of the three p-type terminal well layers 41 has an annular shape. Each of the three p-type terminal well layers 41 surrounds IGBT region 1 and the plurality of diode regions 2.

N+-type channel stopper layer 42 is provided in terminal region 4. N+-type channel stopper layer 42 defines a portion of first surface 71 (see FIG. 2). In plan view, n+-type channel stopper layer 42 has an annular shape. N+-type channel stopper layer 42 surrounds p-type terminal well layer 41.

A terminal electrode 10a is provided on p-type terminal well layer 41 and n+-type channel stopper layer 42. Terminal electrode 10a is electrically connected to p-type terminal well layer 41 and n+-type channel stopper layer 42.

A terminal protection film 5 is provided in terminal region 4. Terminal protection film 5 covers front surface electrode 10, terminal electrode 10a, and interlayer insulating film 34. Terminal protection film 5 is made, for example, of polyimide. An end face of terminal protection film 5 closer to IGBT region 1 serves as a boundary between terminal region 4 and IGBT region 1.

P-type terminal collector layer 36a is provided in third direction 103 with respect to n-type buffer layer 37. P-type terminal collector layer 36a is in contact with n-type buffer layer 37. P-type terminal collector layer 36a is provided in terminal region 4. P-type terminal collector layer 36a defines a portion of second surface 72 (see FIG. 2). P-type terminal collector layer 36a is substantially identical in configuration to p-type collector layer 36.

A function and effect of semiconductor apparatus 100 according to the first embodiment will now be described.

The RC-IGBT generates heat when it conducts, starts conduction, and ends conduction. Specifically, when IGBT region 1 conducts, IGBT region 1 generates heat. A copper circuit pattern may be connected to back surface electrode 11 of the RC-IGBT. In this case, a portion of the RC-IGBT close to back surface electrode 11 has heat dissipated by using the copper circuit pattern. However, when a short circuit is caused in the RC-IGBT, particularly large heat generation occurs at a portion of IGBT region 1 close to front surface electrode 10. In this case, the RC-IGBT may be instantaneously damaged by the heat generation.

For semiconductor apparatus 100 according to the first embodiment, bonded surface 55 of interconnection member 50 covers at least a portion of each of the plurality of diode regions 2 in plan view. In plan view, second diode region 22 is located in first direction 101 with respect to first diode region 21. Second diode region 22 is spaced from first diode region 21. In plan view, third diode region 23 is located in second direction 102 with respect to first diode region 21. Third diode region 23 is spaced from each of first diode region 21 and second diode region 22. This allows the plurality of diode regions 2 to be in contact with IGBT region 1 in an increased area. This in turn allows heat generated by IGBT region 1 to be efficiently transferred from IGBT region 1 to the plurality of diode regions 2. Further, bonded surface 55 that covers at least a portion of each of the plurality of diode regions 2 allows efficient heat transfer from each of the plurality of diode regions 2 to interconnection member 50. As a result, enhanced heat dissipation can be provided at a portion of semiconductor apparatus 100 close to front surface electrode 10.

Semiconductor apparatus 100 according to the first embodiment enables enhanced heat dissipation at a portion of semiconductor apparatus 100 close to front surface electrode 10. This can prevent semiconductor apparatus 100 from locally having an excessively high temperature when a short circuit is caused in the RC-IGBT. As a result, semiconductor apparatus 100 can have an increased short circuit withstand time.

Semiconductor apparatus 100 according to the first embodiment has first diode region 21 in a rectangular shape in plan view. Interconnection member 50 includes flat plate portion 49 and conductive plate portion 51. Connecting portion 59 between flat plate portion 49 and conductive plate portion 51 extends in a direction in which the longer side of first diode region 21 extends. When this is compared with connecting portion 59 extending in a direction in which the shorter side of first diode region 21 extends, the former can improve in uniformity a current passing between first diode region 21 and connecting portion 59. This can in turn suppress an increase in amount of heat generated as a current locally concentrates. As a result, semiconductor apparatus 100 can provide enhanced heat dissipation while the plurality of diode regions 2 conduct.

### First Modification of First Embodiment

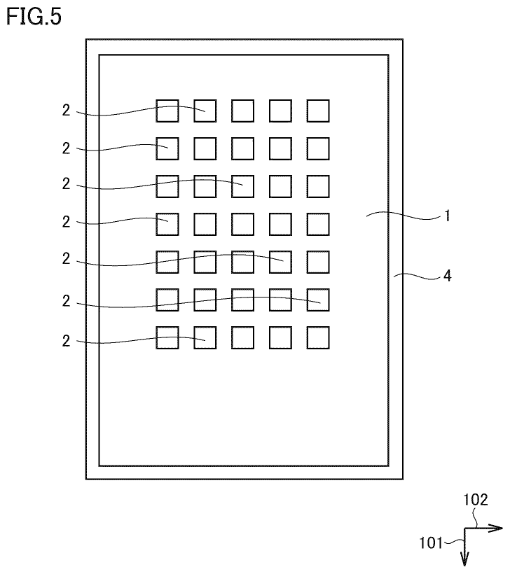

A configuration of semiconductor apparatus 100 according to a first modification of the first embodiment will now be described with reference to FIG. 5. For the sake of convenience for illustration, front surface electrode 10 is not shown in FIG. 5.

While in the above description has been described a configuration in which each of the plurality of diode regions 2 has a rectangular shape in plan view, the configuration of semiconductor apparatus 100 according to the present disclosure is not limited to the configuration described above. Specifically, as shown in FIG. 5, each of the plurality of diode regions 2 may have a square shape in plan view. From another viewpoint, a length of diode region 2 in first direction 101 and a length of diode region 2 in second direction 102 may be substantially equal. Each of the plurality of diode regions 2 has one side substantially parallel to first direction 101.

This can reduce a difference in uniformity between a current passing between the plurality of diode regions 2 and connecting portion 59 of interconnection member 50 when connecting portion 59 extends in first direction 101 and a current passing between the plurality of diode regions 2 and connecting portion 59 when connecting portion 59 extends in second direction 102. From another viewpoint, semiconductor apparatus 100 can provide sufficiently enhanced heat dissipation both when connecting portion 59 extends in first direction 101 and when connecting portion 59 extends in second direction 102. This allows arrangement of conductive plate portion 51 to be determined while interconnection between conductive plate portion 51 and an external device is considered while maintaining heat dissipation of the plurality of diode regions 2. As a result, an increased degree of freedom for interconnection can be achieved.

### Second Modification of First Embodiment

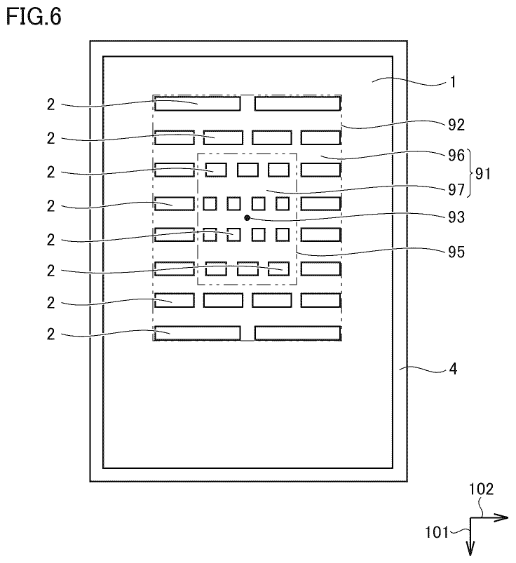

A configuration of semiconductor apparatus 100 according to a second modification of the first embodiment will now be described with reference to FIG. 6. Front surface electrode 10 is not shown in FIG. 6.

As shown in FIG. 6, the plurality of diode regions 2 may be low in density at a center of a region in which the plurality of diode regions 2 are disposed. Specifically, in plan view, a minimum rectangular region surrounding all of the plurality of diode regions 2 is represented as a virtual region 91. A virtual line located between a peripheral edge of virtual region 91 (or a first peripheral edge 92) and a center of virtual region 91 (or a first center 93) intermediately, serves as a boundary line 95.

Virtual region 91 includes an outer peripheral region 96 and a central region 97. Outer peripheral region 96 is located between first peripheral edge 92 and boundary line 95. Central region 97 is located inside boundary line 95. Central region 97 is contiguous to outer peripheral region 96. Central region 97 is surrounded by outer peripheral region 96.

In plan view, the plurality of diode regions 2 is smaller in density in central region 97 than in outer peripheral region 96. Diode region 2 in central region 97 may be smaller in size than diode region 2 in outer peripheral region 96. Specifically, for example, diode region 2 in central region 97 is smaller in length in second direction 102 than diode region 2 in outer peripheral region 96 is.

Diode region 2 in central region 97 may be substantially equal in length in first direction 101 to diode region 2 in outer peripheral region 96. In plan view, the plurality of diode regions 2 may include diode region 2 having a square shape and diode region 2 having a rectangular shape.

When the plurality of diode regions 2 conduct, central region 97 is prone to be higher in temperature than outer peripheral region 96. For semiconductor apparatus 100 according to the second modification of the first embodiment, in plan view, the plurality of diode regions 2 is smaller in density in central region 97 than in outer peripheral region 96. This can prevent central region 97 from having an excessively higher temperature than outer peripheral region 96 when the plurality of diode regions 2 conduct. This enables enhanced heat dissipation at a portion of semiconductor apparatus 100 close to front surface electrode 10 when the plurality of diode regions 2 conduct.

### Third Modification of First Embodiment

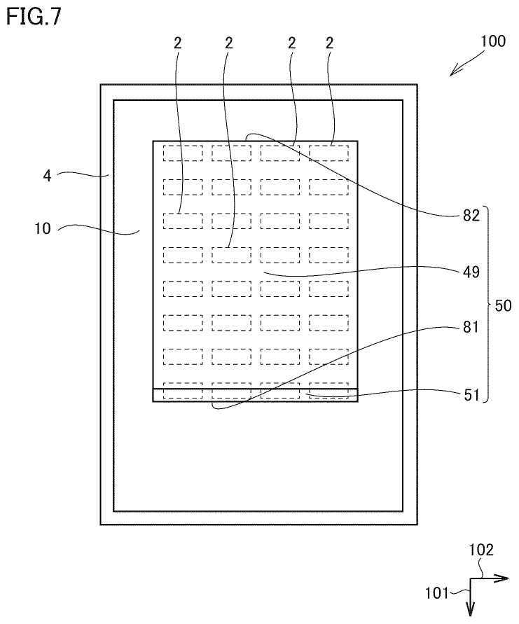

A configuration of semiconductor apparatus 100 according to a third modification of the first embodiment will now be described with reference to FIG. 7. As shown in FIG. 7, interconnection member 50 may cover the plurality of diode regions 2 entirely. Specifically, in plan view, bonded surface 55 (see FIG. 2) may cover the plurality of diode regions 2 entirely. In plan view, bonding member 60 (see FIG. 2) may cover the plurality of diode regions 2 entirely. From another viewpoint, in plan view, the plurality of diode regions 2 are surrounded by the peripheral edge of flat plate portion 49.

This can further increase thermal energy transferred from the plurality of diode regions 2 to interconnection member 50 via front surface electrode 10 and bonding member 60. This enables further enhanced heat dissipation at a portion of semiconductor apparatus 100 close to front surface electrode 10.

While in the above description has been described a configuration in which first diode region 21 is located at a corner of the plurality of diode regions 2, first diode region 21 may not be located at the corner of the plurality of diode regions 2. Diode region 2 may be provided in a direction opposite to first direction 101 and a direction opposite to second direction 102 with respect to first diode region 21.

### Second Embodiment

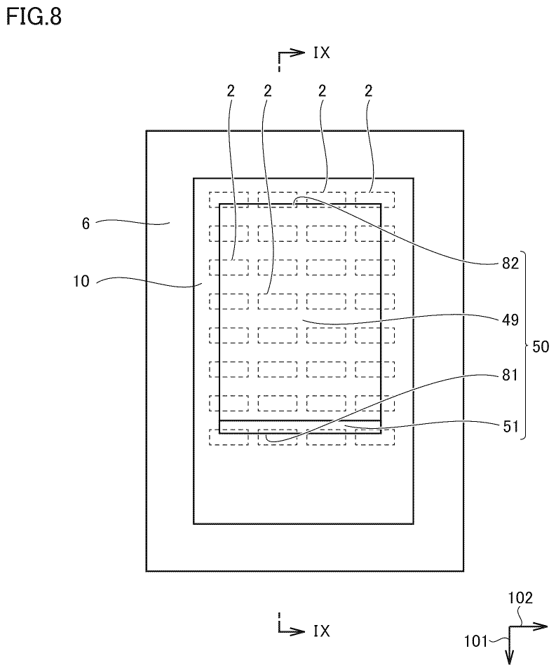

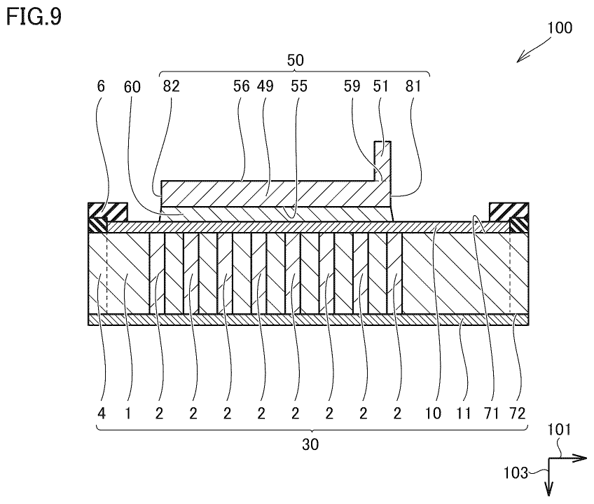

A configuration of semiconductor apparatus 100 according to a second embodiment will now be described with reference to FIGS. 8 and 9. Semiconductor apparatus 100 according to the second embodiment is different from semiconductor apparatus 100 according to the first embodiment mainly in that the former comprises a protective film 6, and the semiconductor apparatus according to the present embodiment has a remainder substantially identical to that of semiconductor apparatus 100 according to the first embodiment. Hereinafter, how the semiconductor apparatus according to the present embodiment differs from semiconductor apparatus 100 according to the first embodiment will mainly be discussed.

As shown in FIGS. 8 and 9, semiconductor apparatus 100 may comprise protective film 6. Protective film 6 is provided on terminal region 4. Protective film 6 covers terminal region 4. Protective film 6 is in contact with front surface electrode 10. Protective film 6 covers a portion of front surface electrode 10. In plan view, protective film 6 surrounds the plurality of diode regions 2. Protective film 6 is formed for example of polyimide, silicon nitride (SiN) film, semi-insulating silicon nitride (SInSiN) film or similar nitride film, or SIPOS (semi-insulating poly-crystalline silicon) or similar oxide film. Protective film 6 provided on terminal region 4 can relax electric field concentration in terminal region 4.

### Third Embodiment

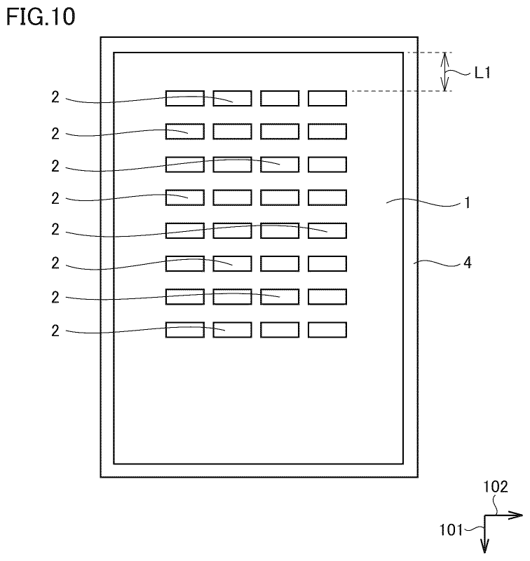

A configuration of semiconductor apparatus 100 according to a third embodiment will now be described with reference to FIGS. 10 to 12. Semiconductor apparatus 100 according to the third embodiment differs from semiconductor apparatus 100 according to the first embodiment mainly in that in plan view a sufficiently large distance is provided between each of the peripheral edge of bonded surface 55 and terminal region 4 and the plurality of diode regions 2, and the semiconductor apparatus according to the present embodiment has a remainder substantially identical to that of semiconductor apparatus 100 according to the first embodiment. Hereinafter, how the semiconductor apparatus according to the present embodiment differs from semiconductor apparatus 100 according to the first embodiment will mainly be discussed.

As shown in FIG. 10, a shortest distance between terminal region 4 and the plurality of diode regions 2 in plan view is represented as a first distance L1. Specifically, first distance L1 is a shortest distance in plan view between terminal protection film 5 of terminal region 4 (see FIG. 4) and n+-type cathode layer 29 (see FIG. 4). First distance L1 is, for example, a shortest distance between terminal region 4 and the plurality of diode regions 2 in first direction 101.

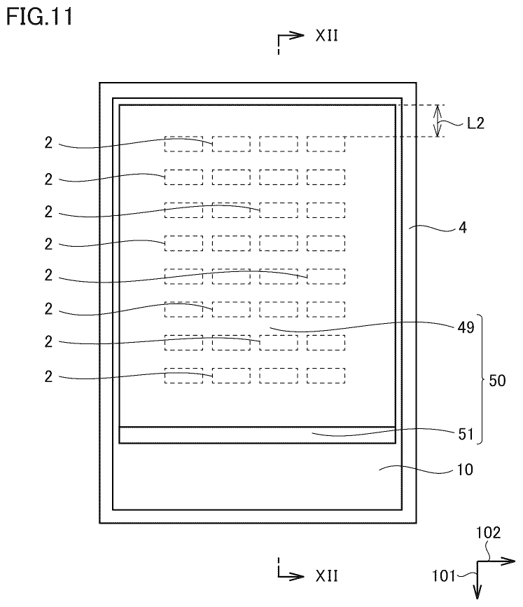

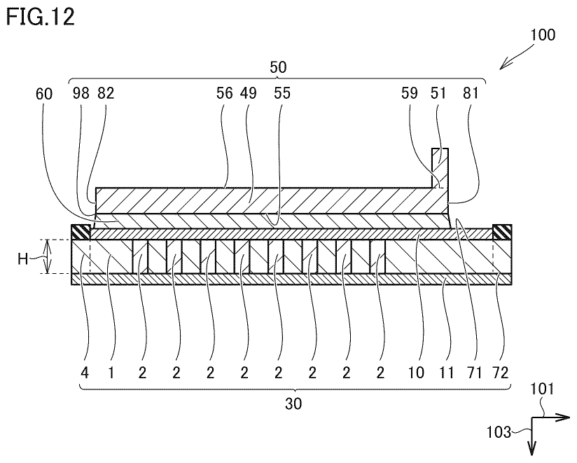

As shown in FIG. 11 and FIG. 12, a shortest distance between the peripheral edge of bonded surface 55 (see FIG. 12) (or a second peripheral edge 98) and the plurality of diode regions 2 in plan view is represented as a second distance L2. Specifically, second distance L2 is a shortest distance between second peripheral edge 98 and n+-type cathode layer 29 (see FIG. 4) in plan view. Second distance L2 is, for example, a shortest distance between second peripheral edge 98 and the plurality of diode regions 2 in first direction 101. In plan view, second peripheral edge 98 may substantially overlap the peripheral edge of flat plate portion 49.

As shown in FIG. 12, a distance between first surface 71 and second surface 72 in third direction 103 is represented as a thickness H of IGBT region 1 in third direction 103. Thickness H is a thickness of semiconductor substrate 70 (see FIG. 4) in third direction 103. Thickness H is substantially equal to a thickness of diode region 2 in third direction 103.

As shown in FIGS. 10 to 12, first distance L1 is equal to or larger than thickness H. Second distance L2 is equal to or larger than thickness H. Second distance L2 is shorter than first distance L1.

Semiconductor apparatus 100 according to the third embodiment has first distance L1 to be equal to or larger than thickness H. Thus, there is a sufficiently large distance between terminal region 4 and the plurality of diode regions 2. This can suppress flowing of holes from terminal region 4 into the plurality of diode regions 2. This can suppress loss of power when the plurality of diode regions 2 conduct.

When the plurality of diode regions 2 conduct, carriers are diffused from diode regions 2 in a direction inclined by 45° or less with respect to third direction 103. Heat is generated in a region in which carriers are diffused. Semiconductor apparatus 100 according to the third embodiment has second distance L2 equal to or larger than thickness H. Therefore, in plan view, bonded surface 55 can cover a region in which carriers diffuse while the plurality of diode regions 2 conduct. Semiconductor apparatus 100 can thus provide further enhanced heat dissipation.

### Fourth Embodiment

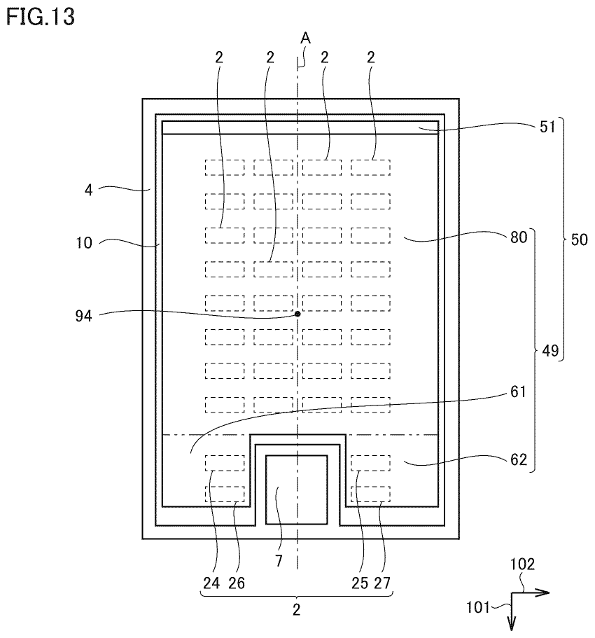

A configuration of semiconductor apparatus 100 according to a fourth embodiment will now be described with reference to FIG. 13. Semiconductor apparatus 100 according to the fourth embodiment is different from semiconductor apparatus 100 according to the first embodiment mainly in that diode region 2 is provided so as to sandwich gate pad 7, and the semiconductor apparatus according to the present embodiment has a remainder substantially identical to that of semiconductor apparatus 100 according to the first embodiment. Hereinafter, how the semiconductor apparatus according to the present embodiment differs from semiconductor apparatus 100 according to the first embodiment will mainly be discussed.

As shown in FIG. 13, semiconductor apparatus 100 comprises gate pad 7. In plan view, gate pad 7 is provided, for example, in first direction 101 with respect to a center of front surface electrode 10 (or a second center 94). Gate pad 7 is adjacent to terminal region 4, for example. In plan view, an imaginary line passing through second center 94 and parallel to first direction 101 is represented as a centerline A. In plan view, centerline A passes, for example, through gate pad 7. Gate pad 7 is configured to receive a signal for controlling conduction of IGBT region 1 (see FIG. 2).

Semiconductor apparatus 100 has gate pad 7 on a side opposite to back surface electrode 11. From another viewpoint, gate pad 7 is provided in a direction opposite to third direction 103 with respect to IGBT region 1.

The plurality of diode regions 2 have two sets of pad sandwiching diode regions. Specifically, the plurality of diode regions 2 include a fourth diode region 24, a fifth diode region 25, a sixth diode region 26, and a seventh diode region 27. Fourth diode region 24, fifth diode region 25, sixth diode region 26, and seventh diode region 27 are spaced from one another.

Fifth diode region 25 is provided in second direction 102 with respect to fourth diode region 24. In second direction 102, fourth diode region 24 and fifth diode region 25 are disposed so as to sandwich gate pad 7. From another viewpoint, in plan view, gate pad 7 is provided between fourth diode region 24 and fifth diode region 25.

Seventh diode region 27 is provided in second direction 102 with respect to sixth diode region 26. In second direction 102, sixth diode region 26 and seventh diode region 27 are disposed so as to sandwich gate pad 7. From another viewpoint, in plan view, gate pad 7 is provided between sixth diode region 26 and seventh diode region 27.

Flat plate portion 49 does not cover gate pad 7. From another viewpoint, in plan view, bonded surface 55 (see FIG. 2) is spaced from gate pad 7. In plan view, a portion of flat plate portion 49 close to gate pad 7 is bifurcated. Specifically, flat plate portion 49 has a main body 80, and a first portion 61 and a second portion 62. First portion 61 is contiguous to main body 80. First portion 61 is provided in first direction 101 with respect to main body 80. In plan view, first portion 61 overlaps each of fourth diode region 24 and sixth diode region 26.

Second portion 62 is contiguous to main body 80. Second portion 62 is provided in first direction 101 with respect to main body 80. Second portion 62 is spaced from first portion 61. Second portion 62 is provided in second direction 102 with respect to first portion 61. Second portion 62 overlaps each of fifth diode region 25 and seventh diode region 27 in plan view. In plan view, gate pad 7 is provided between first portion 61 and second portion 62.

In plan view, conductive plate portion 51 is provided, for example, in a direction opposite to gate pad 7 with respect to second center 94. From another viewpoint, in plan view, conductive plate portion 51 is provided, for example, in a direction opposite to first direction 101 with respect to second center 94. In plan view, second center 94 is located, for example, between conductive plate portion 51 and gate pad 7.

For semiconductor apparatus 100 of the fourth embodiment, the plurality of diode regions 2 include fourth diode region 24 and fifth diode region 25. Gate pad 7 is provided between fourth diode region 24 and fifth diode region 25. When this is compared with absence of fourth diode region 24 and fifth diode region 25, the former can reduce the plurality of diode regions 2 in density for a given total area of the plurality of diode regions 2 in plan view. This enables enhanced heat dissipation at a portion of semiconductor apparatus 100 close to front surface electrode 10 when the plurality of diode regions 2 conduct.

For semiconductor apparatus 100 according to the fourth embodiment, flat plate portion 49 has first portion 61 and second portion 62. In plan view, first portion 61 overlaps fourth diode region 24. In plan view, second portion 62 overlaps fifth diode region 25. This can increase heat energy transferred from each of fourth diode region 24 and fifth diode region 25 to interconnection member 50. This enables enhanced heat dissipation in fourth diode region 24 and fifth diode region 25.

For semiconductor apparatus 100 according to the fourth embodiment, conductive plate portion 51 is provided in a direction opposite to gate pad 7 with respect to second center 94 in plan view. This can suppress interference between gate interconnection connected to gate pad 7 and conductive plate portion 51. An increased degree of freedom for interconnection can thus be achieved.

The plurality of diode regions 2 may have one pair of pads sandwiching diode regions. In other words, the plurality of diode regions 2 may not have sixth diode region 26 and seventh diode region 27.

### Fifth Embodiment

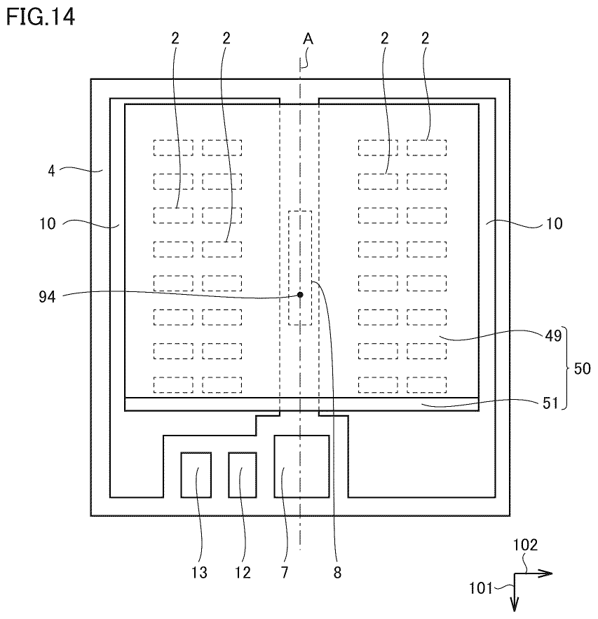

A configuration of semiconductor apparatus 100 according to a fifth embodiment will now be described with reference to FIG. 14. Semiconductor apparatus 100 according to the fifth embodiment is different from semiconductor apparatus 100 according to the fourth embodiment mainly in that bonded surface 55 covers a temperature sensing diode 8, and the semiconductor apparatus according to the present embodiment has a remainder substantially identical to that of semiconductor apparatus 100 according to the fourth embodiment. Hereinafter, how the semiconductor apparatus according to the present embodiment differs from semiconductor apparatus 100 according to the fourth embodiment will mainly be discussed.

As shown in FIG. 14, semiconductor apparatus 100 comprises temperature sensing diode 8, and an anode pad 12 and a cathode pad 13. In plan view, temperature sensing diode 8 is provided between any two of the plurality of diode regions 2. Temperature sensing diode 8 is provided, for example, in a vicinity of the center of semiconductor apparatus 100. Specifically, in plan view, second center 94 may overlap temperature sensing diode 8. In plan view, centerline A may pass through temperature sensing diode 8. In plan view, flat plate portion 49 covers temperature sensing diode 8. From another viewpoint, in plan view, bonded surface 55 (see FIG. 2) covers temperature sensing diode 8.

Anode pad 12 is electrically connected to temperature sensing diode 8. Cathode pad 13 is electrically connected to temperature sensing diode 8. In plan view, flat plate portion 49 does not cover each of anode pad 12 and cathode pad 13. In other words, in plan view, bonded surface 55 (see FIG. 2) is spaced from each of anode pad 12 and cathode pad 13.

In plan view, conductive plate portion 51 may be provided in first direction 101 with respect to second center 94. In plan view, conductive plate portion 51 may be provided between second center 94 and gate pad 7. When semiconductor apparatus 100 comprises a plurality of front surface electrodes 10, second center 94 is a center of a smallest rectangular region surrounding all of the plurality of surface electrodes 10 in plan view.

Semiconductor apparatus 100 according to the fifth embodiment has bonded surface 55 covering temperature sensing diode 8. This can help transferring heat from temperature sensing diode 8 to interconnection member 50. This can enhance heat dissipation of temperature sensing diode 8.

Temperature sensing diode 8 may be provided along gate pad 7. Temperature sensing diode 8 may be provided in first direction 101 with respect to second center 94.

### Sixth Embodiment

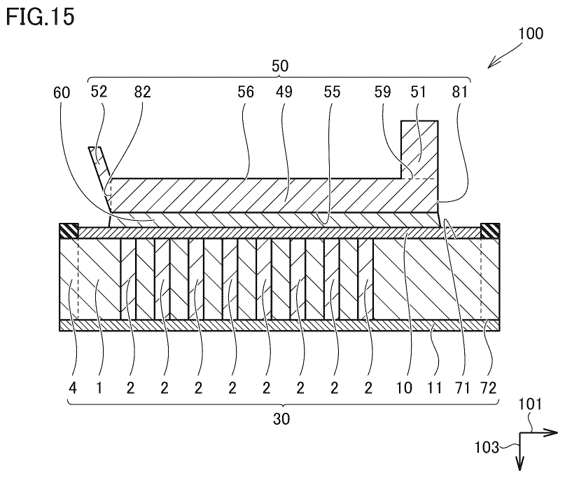

A configuration of semiconductor apparatus 100 according to a sixth embodiment will now be described with reference to FIG. 15. Semiconductor apparatus 100 according to the sixth embodiment differs from semiconductor apparatus 100 according to the first embodiment mainly in that interconnection member 50 has a raised portion 52, and the semiconductor apparatus according to the present embodiment has a remainder substantially identical to that of semiconductor apparatus 100 according to the first embodiment. Hereinafter, how the semiconductor apparatus according to the present embodiment differs from semiconductor apparatus 100 according to the first embodiment will mainly be discussed. The cross section shown in FIG. 15 corresponds to the cross section shown in FIG. 2.

As shown in FIG. 15, interconnection member 50 has raised portion 52. Raised portion 52 is contiguous to flat plate portion 49. Raised portion 52 is different from conductive plate portion 51. At second end 82, raised portion 52 is contiguous to flat plate portion 49. Raised portion 52 is spaced from conductive plate portion 51. Raised portion 52 is inclined with respect to flat plate portion 49 in a direction from front surface electrode 10 toward flat plate portion 49. An inclination angle of raised portion 52 with respect to flat plate portion 49 is not particularly limited.

For semiconductor apparatus 100 of the sixth embodiment, interconnection member 50 has raised portion 52. When this is compared with interconnection member 50 without raised portion 52, the former allows interconnection member 50 to have an increased surface area. This enables enhanced heat dissipation from interconnection member 50 to the outside of semiconductor apparatus 100.

### Modification of Sixth Embodiment

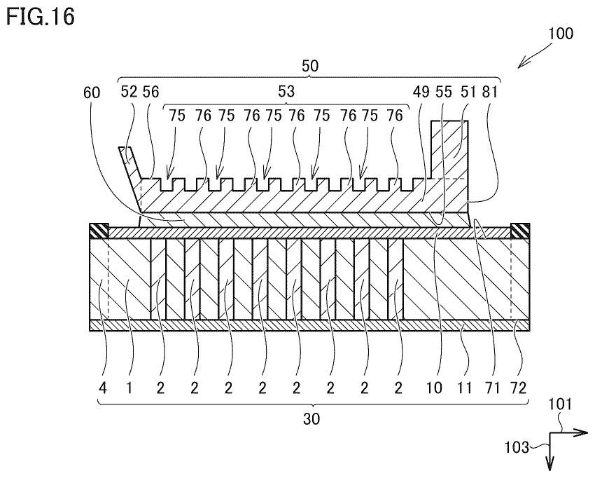

As shown in FIG. 16, a first uneven portion 53 may be provided on front surface 56 of flat plate portion 49. Specifically, a plurality of first depressions 75 and a plurality of first protrusions 76 may be provided on front surface 56. The plurality of first protrusions 76 are spaced from one another. In first direction 101, the plurality of first protrusions 76 are provided between conductive plate portion 51 and raised portion 52. First depression 75 is provided between two adjacent first protrusions 76. Each of the plurality of first protrusions 76 extends for example in second direction 102. The plurality of first depressions 75 and the plurality of first protrusions 76 are not particularly limited in size.

For semiconductor apparatus 100 according to the modification of the sixth embodiment, first uneven portion 53 is provided on front surface 56 of flat plate portion 49. This can provide interconnection member 50 with a further increased surface area. As a result, semiconductor apparatus 100 can provide further enhanced heat dissipation.

### Seventh Embodiment

A configuration of semiconductor apparatus 100 according to a seventh embodiment will now be described. Semiconductor apparatus 100 according to the seventh embodiment is different from semiconductor apparatus 100 according to the sixth embodiment mainly in that flat plate portion 49 has a third protrusion 79, and the semiconductor apparatus according to the present embodiment has a remainder substantially identical to that of semiconductor apparatus 100 according to the sixth embodiment. Hereinafter, how the semiconductor apparatus according to the present embodiment differs from semiconductor apparatus 100 according to the sixth embodiment will mainly be discussed.

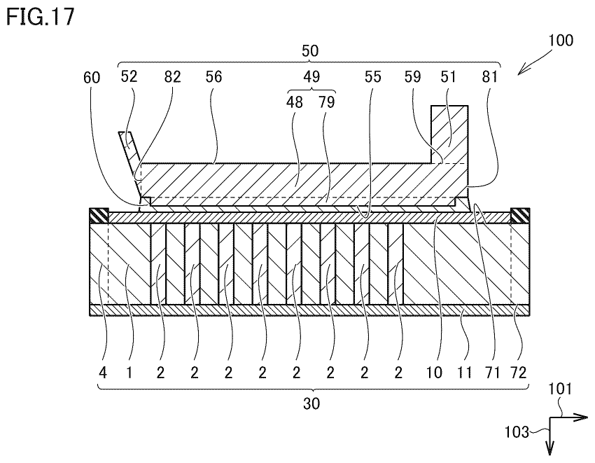

As shown in FIG. 17, flat plate portion 49 includes a plate-shaped portion 48 and third protrusion 79. Plate-shaped portion 48 is a portion which defines front surface 56, first end 81, and second end 82. Third protrusion 79 is provided in third direction 103 with respect to plate-shaped portion 48. Third protrusion 79 protrudes in third direction 103. Plate-shaped portion 48 and third protrusion 79 define bonded surface 55. Third protrusion 79 is in contact with bonding member 60. Third protrusion 79 may have a bottom surface for example in a plane or protruding in third direction 103. Third protrusion 79 may be spaced from front surface electrode 10. In plan view, third protrusion 79 is surrounded for example by bonding member 60. In plan view, for example, third protrusion 79 may cover the plurality of diode regions 2 entirely.

For semiconductor apparatus 100 according to the seventh embodiment, flat plate portion 49 has third protrusion 79. Therefore, in a process for manufacturing semiconductor apparatus 100, third protrusion 79 extrudes bonding member 60 outwards in a direction in a plane perpendicular to third direction 103 before the bonding member solidifies. This allows flat plate portion 49 and bonding member 60 to be effectively brought into close contact with each other. This in turn suppresses formation of voids at a boundary between flat plate portion 49 and bonding member 60.

### Eighth Embodiment

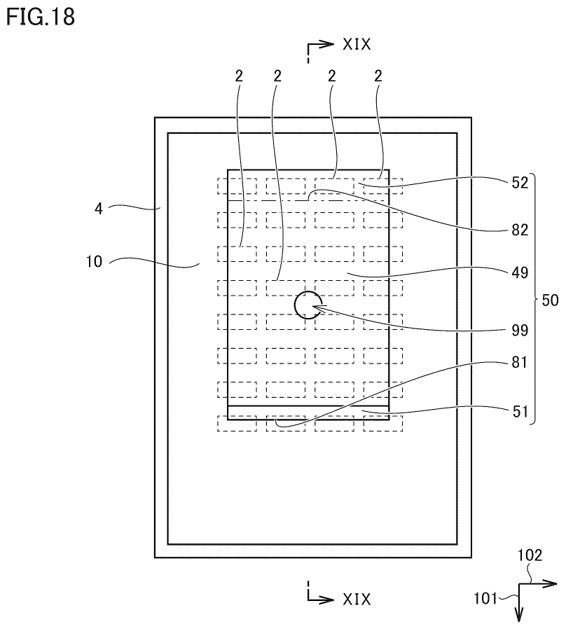

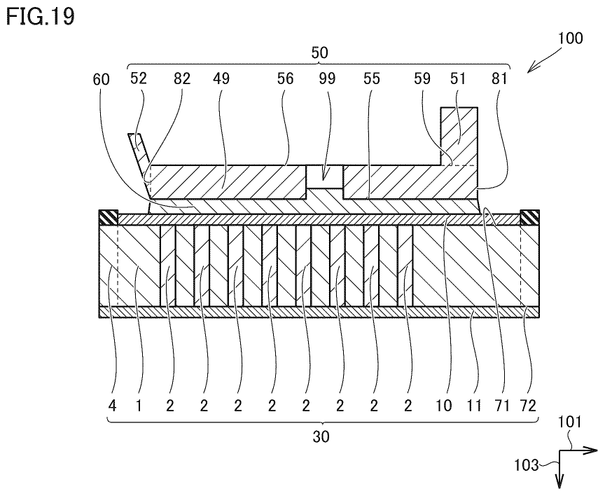

A configuration of semiconductor apparatus 100 according to an eighth embodiment will now be described with reference to FIGS. 18 and 19. Semiconductor apparatus 100 according to the eighth embodiment is different from semiconductor apparatus 100 according to the sixth embodiment mainly in that flat plate portion 49 is provided with a through hole 99, and the semiconductor apparatus according to the present embodiment has a remainder substantially identical to that of semiconductor apparatus 100 according to the sixth embodiment. Hereinafter, how the semiconductor apparatus according to the present embodiment differs from semiconductor apparatus 100 according to the sixth embodiment will mainly be discussed.

As shown in FIGS. 18 and 19, flat plate portion 49 is provided with at least one or more through holes 99. Specifically, one through hole 99 may be provided, or two or more through holes may be provided. Through hole 99 extends in third direction 103. Through hole 99 penetrates front surface 56 and bonded surface 55. A portion of bonding member 60 is located in through hole 99.

In the process for manufacturing semiconductor apparatus 100, when front surface electrode 10 and interconnection member 50 are bonded together using bonding member 60, bonding member 60 is heated. As bonding member 60 thermally expands, bonding member 60 applies pressure to semiconductor device 30. Semiconductor apparatus 100 according to the eighth embodiment has flat plate portion 49 provided with at least one or more through holes 99. Therefore, when front surface electrode 10 and interconnection member 50 are bonded together using bonding member 60, bonding member 60 wets and spreads inside through hole 99. This can reduce the pressure applied from bonding member 60 to semiconductor device 30 when front surface electrode 10 and interconnection member 50 are bonded together. As a result, cracking of semiconductor device 30 can be suppressed.

### Ninth Embodiment

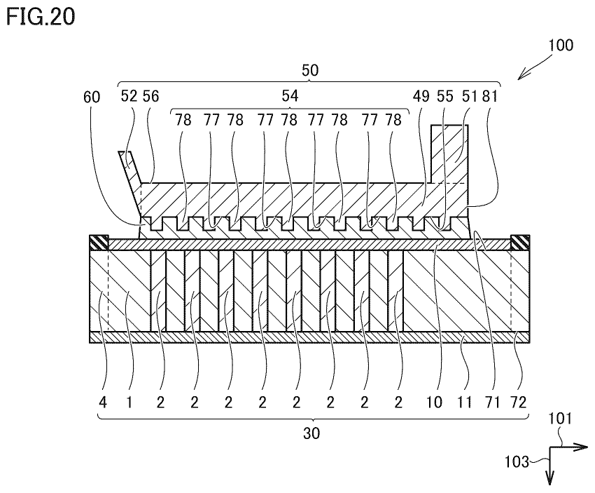

A configuration of semiconductor apparatus 100 according to a ninth embodiment will now be described with reference to FIG. 20. Semiconductor apparatus 100 according to the ninth embodiment is different from semiconductor apparatus 100 according to the sixth embodiment mainly in that bonded surface 55 is provided with a second uneven portion 54, and the semiconductor apparatus according to the present embodiment has a remainder substantially identical to that of semiconductor apparatus 100 according to the sixth embodiment. Hereinafter, how the semiconductor apparatus according to the present embodiment differs from semiconductor apparatus 100 according to the sixth embodiment will mainly be discussed.

As shown in FIG. 20, bonded surface 55 is provided with second uneven portion 54. Specifically, bonded surface 55 is provided with a plurality of second depressions 77 and a plurality of second protrusions 78. The plurality of second protrusions 78 are spaced from one another. In first direction 101, the plurality of second protrusions 78 are provided between conductive plate portion 51 and raised portion 52. Second depression 77 is provided between two adjacent second protrusions 78. Each of the plurality of second protrusions 78 extends, for example, in second direction 102. Second uneven portion 54 is in contact with bonding member 60. The plurality of second depressions 77 and the plurality of second protrusions 78 are not particularly limited in size.

Semiconductor apparatus 100 according to the ninth embodiment has bonded surface 55 provided with second uneven portion 54. This can provide an anchoring effect allowing enhanced bonding strength between front surface electrode 10 and interconnection member 50 using bonding member 60. Specifically, when front surface electrode 10 and interconnection member 50 are bonded together using bonding member 60, bonding member 60 molten enters second uneven portion 54. This can effectively bring interconnection member 50 and bonding member 60 into close contact with each other. As a result, an enhanced bonding strength between front surface electrode 10 and interconnection member 50 can be achieved.

While a configuration with interconnection member 50 having raised portion 52 has been described in the modification of the sixth embodiment and the seventh to ninth embodiments, the configuration of interconnection member 50 is not limited to the above configuration. Specifically, interconnection member 50 may not have raised portion 52.

It should be understood that the embodiments disclosed herein have been described for the purpose of illustration only and in a non-restrictive manner in any respect. The scope of the present disclosure is defined by the terms of the claims, rather than the description above, and is intended to include any modifications within the meaning and scope equivalent to the terms of the claims.

Hereinafter, aspects of the present disclosure will be summarized as additional notes.

### Additional Note 1

A semiconductor apparatus comprising:
an insulated gate bipolar transistor region;
a plurality of diode regions in contact with the insulated gate bipolar transistor region;
a front surface electrode in contact with the insulated gate bipolar transistor region and the plurality of diode regions;
a bonding member provided on the front surface electrode; and
an interconnection member bonded to the front surface electrode by the bonding member,
the insulated gate bipolar transistor region and the plurality of diode regions configuring a reverse conducting insulated gate bipolar transistor,
the interconnection member having a bonded surface in contact with the bonding member,
in a plan view seen in a direction perpendicular to the front surface electrode, the bonded surface covering at least a portion of each of the plurality of diode regions,
in the plan view, the plurality of diode regions including
   a first diode region,
   a second diode region located in a first direction with respect to the first diode region and spaced from the first diode region, and
   a third diode region located in a second direction with respect to the first diode region, the second direction being perpendicular to the first direction, and spaced from each of the first and second diode regions.

### Additional Note 2

The semiconductor apparatus according to Additional Note 1, wherein the interconnection member includes:
a flat plate portion that defines the bonded surface; and
a conductive plate portion contiguous to the flat plate portion and spaced from the bonding member.

### Additional Note 3

The semiconductor apparatus according to Additional Note 2, wherein
in the plan view, the first diode region has a rectangular shape, and
a connecting portion between the flat plate portion and the conductive plate portion extends in a direction in which a longer side of the first diode region extends.

### Additional Note 4

The semiconductor apparatus according to Additional Note 2 or 3, further comprising a gate pad provided in a direction from the insulated gate bipolar transistor region toward the front surface electrode with respect to the insulated gate bipolar transistor region and receiving a signal for controlling conduction of the insulated gate bipolar transistor region, wherein
the plurality of diode regions include a fourth diode region and a fifth diode region spaced from the fourth diode region,
in the plan view, the gate pad is provided between the fourth diode region and the fifth diode region,
in the plan view, the bonded surface is spaced from the gate pad,
the flat plate portion includes
   a first portion overlapping the fourth diode region in the plan view and
   a second portion overlapping the fifth diode region in the plan view, and
the second portion is spaced from the first portion.

### Additional Note 5

The semiconductor apparatus according to Additional Note 4, wherein
in the plan view, the gate pad is provided in the first direction with respect to a center of the front surface electrode, and
in the plan view, the conductive plate portion is provided in a direction opposite to the gate pad with respect to the center of the front surface electrode.

### Additional Note 6

The semiconductor apparatus according to any one of Additional Notes 2 to 5, wherein
the interconnection member has a raised portion contiguous to the flat plate portion and different from the conductive plate portion, and
the raised portion is inclined with respect to the flat plate portion in a direction from the front surface electrode toward the flat plate portion.

### Additional Note 7

The semiconductor apparatus according to any one of Additional Notes 2 to 6, wherein
the flat plate portion has a front surface opposite to the bonded surface, and
the front surface is provided with a first uneven portion.

### Additional Note 8

The semiconductor apparatus according to any one of Additional Notes 2 to 7, wherein
the flat plate portion has a protrusion protruding in a direction from the flat plate portion toward the front surface electrode, and
the protrusion defines a portion of the bonded surface.

### Additional Note 9

The semiconductor apparatus according to any one of Additional Notes 2 to 8, wherein the flat plate portion is provided with at least one or more through holes.

### Additional Note 10

The semiconductor apparatus according to any one of Additional Notes 2 to 9, wherein
the bonded surface is provided with a second uneven portion, and
the second uneven portion is in contact with the bonding member.

### Additional Note 11

The semiconductor apparatus according to Additional Note 1 or 2, wherein in the plan view, each of the plurality of diode regions has a square shape.

### Additional Note 12

The semiconductor apparatus according to any one of Additional Notes 1 to 11, wherein
when in the plan view a minimum rectangular region surrounding all of the plurality of diode regions is represented as a virtual region and a virtual line located between a peripheral edge of the virtual region and a center of the virtual region intermediately is defined as a boundary line,
the virtual region is composed of
   an outer peripheral region located between the peripheral edge of the virtual region and the boundary line and
   a central region located inside the boundary line and contiguous to the outer peripheral region, and
in the plan view, the plurality of diode regions in the central region is smaller in density than the plurality of diode regions in the outer peripheral region.

### Additional Note 13

The semiconductor apparatus according to any one of Additional Notes 1 to 12, wherein in the plan view the bonded surface covers the plurality of diode regions entirely.

### Additional Note 14

The semiconductor apparatus according to any one of Additional Notes 1 to 13, further comprising:
a terminal region in contact with the insulated gate bipolar transistor region and surrounding the insulated gate bipolar transistor region and the plurality of diode regions; and
a protective film provided on the terminal region.

### Additional Note 15

The semiconductor apparatus according to any one of Additional Notes 1 to 13, further comprising a terminal region in contact with the insulated gate bipolar transistor region and surrounding the insulated gate bipolar transistor region and the plurality of diode regions, wherein
a shortest distance between the terminal region and the plurality of diode regions in the plan view is equal to or larger than a thickness of the insulated gate bipolar transistor region in the direction perpendicular to the front surface electrode.

### Additional Note 16

The semiconductor apparatus according to any one of Additional Notes 1 to 15, wherein a shortest distance between a peripheral edge of the bonded surface and the plurality of diode regions in the plan view is equal to or larger than a thickness of the insulated gate bipolar transistor region in the direction perpendicular to the front surface electrode.

### Additional Note 17

The semiconductor apparatus according to any one of Additional Notes 1 to 16, further comprising a temperature sensing diode provided between any two of the plurality of diode regions in the plan view, wherein
in the plan view, the bonded surface covers the temperature sensing diode.

What is claimed is:

1. A semiconductor apparatus comprising:
an insulated gate bipolar transistor region;
a plurality of diode regions in contact with the insulated gate bipolar transistor region;
a front surface electrode in contact with the insulated gate bipolar transistor region and the plurality of diode regions;
a bonding member provided on the front surface electrode; and
an interconnection member bonded to the front surface electrode by the bonding member,
the insulated gate bipolar transistor region and the plurality of diode regions configuring a reverse conducting insulated gate bipolar transistor,
the interconnection member having a bonded surface in contact with the bonding member,
in a plan view seen in a direction perpendicular to the front surface electrode, the bonded surface covering at least a portion of each of the plurality of diode regions,
in the plan view, the plurality of diode regions including
a first diode region,
a second diode region located in a first direction with respect to the first diode region and spaced from the first diode region, and
a third diode region located in a second direction with respect to the first diode region, the second direction being perpendicular to the first direction, and spaced from each of the first diode region and the second diode region.

2. The semiconductor apparatus according to claim 1, wherein the interconnection member includes:
a flat plate portion that defines the bonded surface; and
a conductive plate portion contiguous to the flat plate portion and spaced from the bonding member.

3. The semiconductor apparatus according to claim 2, wherein
in the plan view, the first diode region has a rectangular shape, and
a connecting portion between the flat plate portion and the conductive plate portion extends in a direction in which a longer side of the first diode region extends.

4. The semiconductor apparatus according to claim 2, further comprising a gate pad provided in a direction from the insulated gate bipolar transistor region toward the front surface electrode with respect to the insulated gate bipolar transistor region and receiving a signal for controlling conduction of the insulated gate bipolar transistor region, wherein
the plurality of diode regions include a fourth diode region and a fifth diode region spaced from the fourth diode region,
in the plan view, the gate pad is provided between the fourth diode region and the fifth diode region,
in the plan view, the bonded surface is spaced from the gate pad,
the flat plate portion includes
a first portion overlapping the fourth diode region in the plan view and
a second portion overlapping the fifth diode region in the plan view, and
the second portion is spaced from the first portion.

5. The semiconductor apparatus according to claim 4, wherein
in the plan view, the gate pad is provided in the first direction with respect to a center of the front surface electrode, and
in the plan view, the conductive plate portion is provided in a direction opposite to the gate pad with respect to the center of the front surface electrode.

6. The semiconductor apparatus according to claim 2, wherein
the interconnection member has a raised portion contiguous to the flat plate portion and different from the conductive plate portion, and
the raised portion is inclined with respect to the flat plate portion in a direction from the front surface electrode toward the flat plate portion.

7. The semiconductor apparatus according to claim 2, wherein
the flat plate portion has a front surface opposite to the bonded surface, and
the front surface is provided with a first uneven portion.

8. The semiconductor apparatus according to claim 2, wherein
the flat plate portion has a protrusion protruding in a direction from the flat plate portion toward the front surface electrode, and
the protrusion defines a portion of the bonded surface.

9. The semiconductor apparatus according to claim 2, wherein the flat plate portion is provided with at least one or more through holes.

10. The semiconductor apparatus according to claim 2, wherein
the bonded surface is provided with a second uneven portion, and
the second uneven portion is in contact with the bonding member.

11. The semiconductor apparatus according to claim 1, wherein in the plan view, each of the plurality of diode regions has a square shape.

12. The semiconductor apparatus according to claim 1, wherein
when in the plan view a minimum rectangular region surrounding all of the plurality of diode regions is represented as a virtual region and a virtual line located between a peripheral edge of the virtual region and a center of the virtual region intermediately is defined as a boundary line,
the virtual region is composed of
an outer peripheral region located between the peripheral edge of the virtual region and the boundary line and
a central region located inside the boundary line and contiguous to the outer peripheral region, and
in the plan view, the plurality of diode regions in the central region is smaller in density than the plurality of diode regions in the outer peripheral region.

13. The semiconductor apparatus according to claim 1, wherein in the plan view the bonded surface covers the plurality of diode regions entirely.

14. The semiconductor apparatus according to claim 1, further comprising:
a terminal region in contact with the insulated gate bipolar transistor region and surrounding the insulated gate bipolar transistor region and the plurality of diode regions; and
a protective film provided on the terminal region.

15. The semiconductor apparatus according to claim 1, further comprising a terminal region in contact with the insulated gate bipolar transistor region and surrounding the insulated gate bipolar transistor region and the plurality of diode regions, wherein
a shortest distance between the terminal region and the plurality of diode regions in the plan view is equal to or larger than a thickness of the insulated gate bipolar transistor region in the direction perpendicular to the front surface electrode.

16. The semiconductor apparatus according to claim 1, wherein a shortest distance between a peripheral edge of the bonded surface and the plurality of diode regions in the plan view is equal to or larger than a thickness of the insulated gate bipolar transistor region in the direction perpendicular to the front surface electrode.

17. The semiconductor apparatus according to claim 1, further comprising a temperature sensing diode provided between any two of the plurality of diode regions in the plan view, wherein
in the plan view, the bonded surface covers the temperature sensing diode.
